(19) United States
(12) Patent Application Publication
(10) Pub. No.: US 2026/0298087 A1
(43) Pub. Date: Oct. 1, 2026

(54) MESHING PLAN UPDATE BASED ON ACTUAL SURFACE MODEL OF A ROCK SURFACE

(71) Applicant: SANDVIK MINING AND CONSTRUCTION OY, Tampere (FI)

(72) Inventors: Ari HAAVISTO, Tampere (FI); Jussi RIIPPI, Tampere (FI); Totte FRANCKE, Tampere (FI); Jarno HELKALA, Tampere (FI)

(21) Appl. No.: 19/480,396

(22) PCT Filed: May 2, 2024
(86) PCT No.: PCT/EP2024/062138

§ 371 Date: Oct. 31, 2025

(30) Foreign Application Priority Data
May 2, 2023 (EP) 23171051.8

(51) Int. Cl. E21D 11/15; G06F 30/13; G06T 5/70

(52) U.S. Cl. CPC E21D 11/152; G06F 30/13; G06T 5/70

(57) ABSTRACT

Present example embodiments may generally relate to the field of mesh installation on a rock surface. An apparatus may obtain a meshing plan indicative of at least one of a planned position of at least one mesh for installation of the at least one mesh to a rock surface, or a planned position of at least one fastener for fastening the at least one mesh to the rock surface; obtain a planned surface model of the rock surface; obtain an actual surface model of the rock surface; detect a discrepancy between the planned surface model and the actual surface model; update the meshing plan based on the detected discrepancy; and control the mesh installation based on the updated meshing plan.

### TECHNICAL FIELD

Various example embodiments generally relate to the field of mesh installation on a rock surface. Some example embodiments relate to updating a meshing plan based on an actual surface model of the rock surface.

### BACKGROUND

In various applications, such as for example underground mining, it may be desired to protect equipment or people from rocks falling from a rock surface. This may be done for example by installing protective meshes on the rock surface. A mesh installation rig may comprise one or more booms with appropriate tools for installing meshes to the rock surface. Positions of the meshes may be determined on-site by a human operator sitting in the cabin of the mesh installation rig. The rock surface might not exactly follow a planned model of the rock surface, for example, because it may be hard to exactly control how explosives behave during excavation.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

According to a first aspect, an apparatus for controlling mesh installation is disclosed. The apparatus may comprise: at least one processor; and at least one memory including computer program code, the at least one memory and the computer program code configured to, with the at least one processor, cause the apparatus at least to: obtain a meshing plan indicative of at least one of: a planned position of at least one mesh for installation of the at least one mesh to a rock surface, or a planned position of at least one fastener for fastening the at least one mesh to the rock surface; obtain a planned surface model of the rock surface; obtain an actual surface model of the rock surface; detect a discrepancy between the planned surface model and the actual surface model; update the meshing plan based on the detected discrepancy; and control the mesh installation based on the updated meshing plan.

According to a second aspect, a mesh installation rig is disclosed. The mesh installation rig may be configured to: obtain a meshing plan indicative of at least one of: a planned position of at least one mesh for installation of the at least one mesh to a rock surface, or a planned position of at least one fastener for fastening the at least one mesh to the rock surface; obtain a planned surface model of the rock surface; obtain an actual surface model of the rock surface; detect a discrepancy between the planned surface model and the actual surface model; update the meshing plan based on the detected discrepancy; and control the mesh installation based on the updated meshing plan.

According to a third aspect, a method for controlling mesh installation is disclosed. The method may comprise: obtaining a meshing plan indicative of at least one of: a planned position of at least one mesh for installation of the at least one mesh to a rock surface, or a planned position of at least one fastener for fastening the at least one mesh to the rock surface; obtaining a planned surface model of the rock surface; obtaining an actual surface model of the rock surface; detecting a discrepancy between the planned surface model and the actual surface model; updating the meshing plan based on the detected discrepancy; and controlling the mesh installation based on the updated meshing plan.

According to a fourth aspect, an apparatus is disclosed. The apparatus may comprise means for obtaining a meshing plan indicative of at least one of: a planned position of at least one mesh for installation of the at least one mesh to a rock surface, or a planned position of at least one fastener for fastening the at least one mesh to the rock surface; means for obtaining a planned surface model of the rock surface; means for obtaining an actual surface model of the rock surface; means for detecting a discrepancy between the planned surface model and the actual surface model; means for updating the meshing plan based on the detected discrepancy; and means for controlling the mesh installation based on the updated meshing plan.

According to a fifth aspect, a computer program is disclosed. The computer program may comprise instructions which, when executed by an apparatus, cause the apparatus at least to: obtain a meshing plan indicative of at least one of: a planned position of at least one mesh for installation of the at least one mesh to a rock surface, or a planned position of at least one fastener for fastening the at least one mesh to the rock surface; obtain a planned surface model of the rock surface; obtain an actual surface model of the rock surface; detect a discrepancy between the planned surface model and the actual surface model; update the meshing plan based on the detected discrepancy; and control the mesh installation based on the updated meshing plan.

Example embodiments of the above aspects are described in the claims, the description, and/or the drawings. According to some aspects, there is provided the subject matter of the independent claims. Some further aspects are defined in the dependent claims. Many of the attendant features will be more readily appreciated as they become better understood by reference to the following description considered in connection with the accompanying drawings.

### LIST OF DRAWINGS

The accompanying drawings, which are included to provide a further understanding of the example embodiments and constitute a part of this specification, illustrate example embodiments and, together with the description, help to explain the example embodiments. In the drawings:

FIG. 1 illustrates an example of a mesh installation rig;

FIG. 2 illustrates an example of a mesh installation rig communicatively coupled to a remote mesh control device;

FIG. 3 illustrates an example of a data structure of a meshing plan;

FIG. 4 illustrates an example of a flow chart for controlling mesh installation;

FIG. 5 illustrates an example of planned and actual surface models;

FIG. 6 illustrates an example of projection of respective curves of the planned and actual surface model on a planar projection of a rock surface;

FIG. 7 illustrates an example of adjusting mesh position;

FIG. 8 illustrates an example of adjusting fastener position;

FIG. 9 illustrates an example of an apparatus configured to practise one or more example embodiments; and

FIG. 10 illustrates an example of a method for controlling mesh installation.

Like references are used to designate like parts in the accompanying drawings.

### DESCRIPTION

Reference will now be made to embodiments, examples of which are illustrated in the accompanying drawings. The description provided below in connection with the appended drawings is intended as a description of the present examples and is not intended to represent the only forms in which the present example may be constructed or utilized. The description sets forth the functions of the example and the sequence of steps for constructing and operating the example. However, the same or equivalent functions and sequences may be accomplished by different examples.

A certain surface profile of a rock surface (e.g., a tunnel) may be planned, but after blasting the profile may include a combination of different levels of under and over breakage. For example, tunnel walls may include lumps and bumps that make meshing difficult. Example embodiments of the present disclosure enable alleviating this issue by identifying discrepancies between the planned and true surface profile, or an error in meshing. A meshing plan may be then adapted by recalculating mesh positions in the meshing plan, recalculating fastener locations (e.g., a bolting plan), omitting meshing or bolting of a section of the rock surface until further drilling or blasting (e.g., in case of under excavation). Furthermore, information indicative of the adjustment of mesh locations and bolt locations may be stored based on actual realization of the meshing. Comparing the planned and true profiles of the rock surface enables to address unplanned bumps and lumps in the true profile, which may result in improving safety of mesh installation. Also, errors or adjustments during meshing may be fixed or monitored more easily.

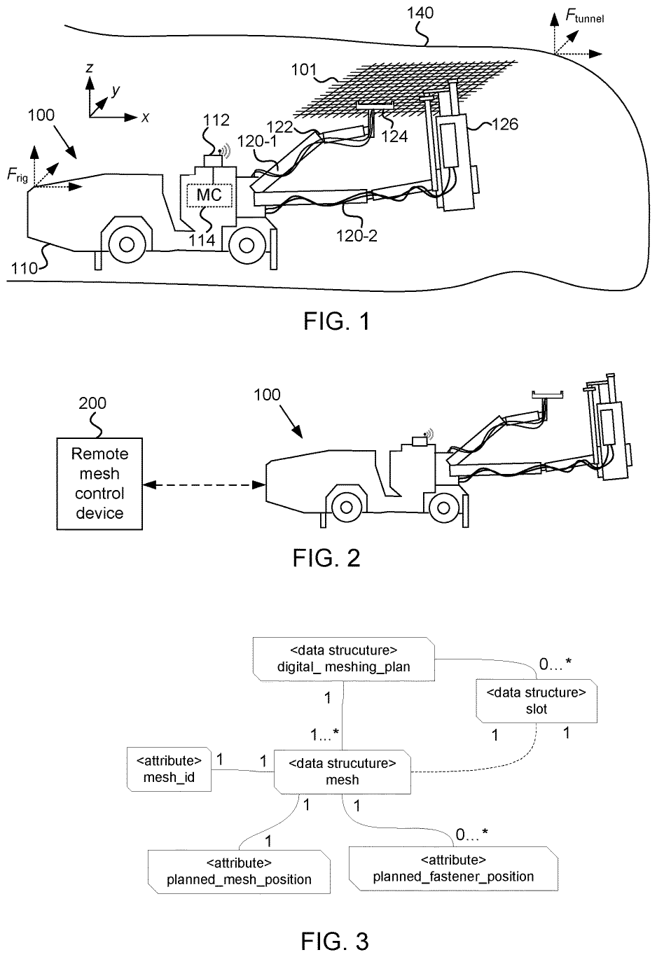

FIG. 1 illustrates an example of a mesh installation rig. Even though mesh installation rig 100 is illustrated as an underground mesh installation rig, example embodiments of the present disclosure may be applied also to other type of mesh installation machines, for example rigs configured for installing meshes on rock cuttings along roads or railways.

Mesh installation rig 100 may be an automated mesh installation rig, for example an automated mining vehicle equipped with tools configured for mesh installation. An automated mining vehicle, for example an automated mesh installation rig, operating in an automatic mode may be configured to, for example, receive a task to be performed, perceive the environment of the automated mining vehicle, and autonomously perform the task while taking the environment into account. An automated mining vehicle operating in an automatic mode may be configured to operate independently but may be taken under external control at certain operation areas or conditions, such as during states of emergencies. Example embodiments may be however applied also in non-autonomous or semi-autonomous mining vehicles, for example remote-controlled mining vehicles.

In the example of FIG. 1, axis x represents the forward driving direction of mesh installation rig 100. Axis y represents the other horizontal direction, in this example towards left from mesh installation rig 100. Axis z represents the vertical direction, in this example towards the roof of the tunnel. Mesh installation rig 100 may comprise a movable carrier 110 and at least one boom 120 connected to movable carrier 110. Movable carrier 110 may comprise equipment for moving or stabilising mesh installation rig 100, such as for example a motor, wheels, or stabilizer jacks. Movable carrier 110 may be configured to move autonomously or it may be controlled by a human operator, either remotely or locally at mesh installation rig 100. Even though two booms 120-1, 120-2 have been illustrated in FIG. 1, mesh installation rig 100 may generally comprise one or a plurality (e.g., two, three, four, . . . ) of booms 120. Boom 120-1 may be referred to as a first boom. Boom 120-2 may be referred to as a second boom.

A gripper 124 may be coupled to a distal end portion of boom 120-1. Gripper 124 may be configured to grab and hold mesh 101, for example to enable boom 120-1 to position mesh 101 at rock surface 140. Rock surface 140 may comprise the roof of the tunnel and/or at least some of the walls of the tunnel. A bolter 126 may be coupled to a distal end portion of boom 120-2. Bolter 126 may be configured to fasten mesh 101 at rock surface 140. Bolting is provided as one example of fastening mesh 101 to rock surface 140, but other means for fastening or mounting, such as for example riveting, may be also used. Bolts and rivets are examples of fasteners suitable for fastening mesh 101 to rock surface 140.

Mesh installation rig 100 may comprise at least one sensor 112 for scanning environment of mesh installation rig 100, for example, rock surface 140 and/or any meshes already installed thereon. Sensor 112 may include for example one or more of the following: a camera, a radio detection and ranging (radar) sensor, a light detection and ranging (lidar) sensor. Sensor 112 may therefore comprise a group of two or more sensors. Sensor 112 may be configured to scan rock surface 140 to detect geometry of rock surface 140 or to detect the meshes, for example particular features thereof, such as edge(s) or corner(s) of the meshes. Scanning rock surface 140 may comprise scanning with sensor 112 such that its sensing direction is towards rock surface 140. Alternatively, or additionally, mesh installation rig 100 may be configured to scan rock surface 140 with a device configured to physically probe rock surface 140. Such device (e.g., a probe) may be connected to a boom of mesh installation rig 100.

A camera may be used to extract depth information of objects such as for example rock surface 140 or mesh 101, for example by comparing two images taken at slightly different positions (e.g., by two camera units). Alternatively, sensor 112 may comprise a time-of-flight (ToF) camera, which may be configured to determine a distance between the camera and the object by measuring a round-trip time of an artificial light signal provided by a laser or a light-emitting diode (LED). A lidar sensor may be configured to determine a distance to different points of the object by targeting the object with a laser and measuring the time for the reflected light to return to a receiver of the lidar sensor. A radar sensor may be configured to transmit electromagnetic energy towards the object and to observe the echoes returned from the object to determine distances to different points of the object.

Based on scanning, mesh installation rig 100 may obtain point cloud data that represents the scanned environment. The point cloud data may for example comprise three-dimensional (3D) model of rock surface 140 or a detected mesh, or at least certain features such as edge(s) of the mesh. Mesh installation rig 100 may be therefore configured to obtain an actual surface model of rock surface 140. A position of the mesh, or certain points such as corners or edges of the mesh, may be also determined based on the scanning data. The position of the mesh may be therefore fixed to, or known in relation to, a coordinate system or frame of mesh installation rig 100 (e.g., coordinate frame F_{rig}). The coordinate frame of mesh installation rig 100 may be stationary with respect to mesh installation rig 100. Mesh controller 114 may be configured to map the position(s) of the detected meshes to a coordinate system that is stationary with respect to rock surface 140 (e.g., coordinate frame Fₜᵤₙₙₑₗ), for example for providing feedback on actual positions of installed meshes on rock surface 140.

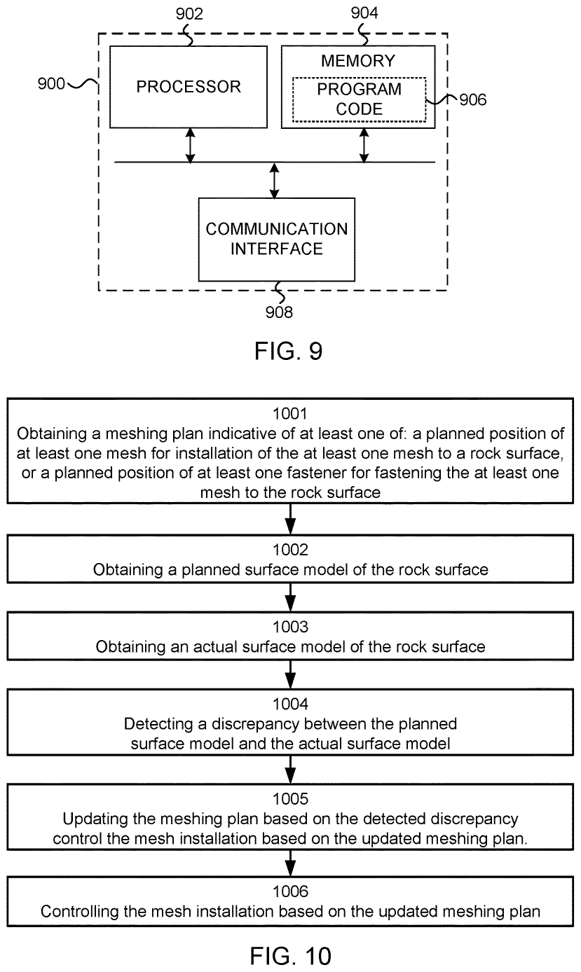

Mesh installation rig 100 may comprise a mesh controller (MC) 114. Mesh controller 114 may be for example provided as a software application residing on a memory and being executable by a processor. An example of an apparatus suitable for implementing mesh controller 114 is provided in FIG. 9. Mesh controller 114 may comprise, or be communicatively coupled to, various functions, blocks, or applications for implementing functionality of mesh controller 114. For example, mesh controller 114 may comprise or be communicatively coupled to a data management server, which may be configured to store information on a digital meshing plan, tunnel lines, point cloud or mesh presentations of tunnel lines or profiles, a mine map point cloud, or the like; or in general a planned surface model of rock surface 140. The planned surface model may comprise an intended profile of a rock surface, for example a tunnel. The planned surface model may be for example generated under supervision of a human operator with a tunnel planning tool. The planned surface model may be provided in a coordinate system that is stationary with respect to rock surface 140 (e.g., Fₜᵤₙₙₑₗ).

The digital meshing plan, also referred to as a meshing plan, may comprise planned mesh positions and optionally also planned fastener positions for fastening mesh(es). A mesh position may comprise a position of a mesh on rock surface 140, for example position of a corner, edge, or centre of mass of the mesh. A fastener position may comprise a position of fastener or fastening means (e.g., a bolt or a rivet) by which the mesh is configured to be fastened to rock surface 140. A planned fastener position may comprise a planned position for a fastener at rock surface 140. Mesh controller 114 may be configured to control installation of mesh 101 based on a planned position of mesh 101 and/or planned fastener position(s) of mesh 101. The planned position of mesh 101 and/or the associated fastener position(s) may be provided with respect to the coordinate system stationary with respect to rock surface 140. Mesh controller 114 may be configured to translate the position(s) to the coordinate system of mesh installation rig 100 (F_{rig}) based on a current position of mesh installation rig in the coordinate system stationary with respect to rock surface 140.

Mesh controller 114 may comprise a navigation application configured to control, or enable a human operator to control, navigation of mesh installation rig 100, for example to move mesh installation rig 100 to a desired position (installation position) for installing a mesh at its planned position on rock surface 140 and/or to determine planned mesh position(s) or planned fastener position(s) of the digital meshing plan relative to a current position of mesh installation rig 100. A position of mesh installation rig 100 may be referred to as a navigation position. An installation position may be therefore a navigation position, which has been planned or determined for mesh installation rig 100 to install a mesh at rock surface 140. Mesh controller 114 may be configured to map positions of the planned surface model to the coordinate system of mesh installation rig 100 (F_{rig}), for example in order to compare the planned surface model of rock surface 140 to the actual surface model obtained based on scanning rock surface 140, for example at the installation position.

Mesh controller 114 may be configured to determine and/or maintain the digital meshing plan, a 3D model of at least one component of mesh installation rig 100 (e.g., a 3D model of boom(s) 120, gripper 124 or bolter 126), and/or a kinematic model of mesh installation rig 100, or component(s) thereof. A 3D model of a component of mesh installation rig 100 may comprise 3D geometry data of the component, obtained for example from a computer aided design (CAD) model of the respective physical component. The digital meshing plan may be provided as part of a drilling plan. The drilling plan may comprise planned drilling positions at rock surface 140, for example for bolting rock surface 140 (with or without meshing) to strengthen rock surface 140.

A kinematic model of mesh installation rig 100, or component(s) thereof, may comprise a mathematical description of at least a part of mesh installation rig 100. A kinematic model may describe motion of mesh installation rig 100 or component(s) of mesh installation rig 100 without taking into account the forces that cause the motion. The kinematic model may be used for estimating or simulation of a position of mesh installation rig 100 or component(s) of mesh installation rig 100, for example based on measurement data from one or more sensors associated with mesh installation rig 100 or motion of mesh installation rig 100 caused, or to be caused, by given control inputs. The kinematic model of mesh installation rig 100 may comprise at least dimensions of mesh installation rig 100 and/or reach of mesh installation rig 100 such as a movement range of at least one boom 120 of mesh installation rig 100. The kinematic model may comprise information on dimensions of boom(s) 120, or parts thereof, for example gripper 124 or bolter 126, characteristics of joint(s) 122 (e.g., their degrees of freedom), constraints between moving parts of mesh installation rig 100, or the like. The kinematic model may thus enable modelling movement of the component(s) of mesh installation rig 100, for example to determine possible positions for installing mesh 101 from a particular installation position or to predict/prevent collisions between component(s) of mesh installation rig, mesh 101, and/or rock surface 140. The kinematic model may for example enable determining a maximum distance reachable by gripper 124 or bolter 126. The 3D model(s) of the component(s) may be provided as point cloud data indicative of the surface of the component(s). Point cloud data may comprise a plurality of data points representing, for example, distances between mesh installation rig 100 and its component(s) or other objects in the environment of mesh installation rig 100, for example at a particular time instance. An individual point included in a point cloud may be presented by, for example, x and y coordinates, or x, y, and z coordinates with respect to a particular coordinate frame (e.g., F_{rig}).

Mesh installation rig 100 may be controlled by a remote mesh control device 200, which may be external to mesh installation rig 100, as illustrated in FIG. 2. Remote mesh control device 200 may be for example a server located remote from mesh installation rig 100, for example outside the tunnel. Functionality of mesh controller 114 may be provided at mesh installation rig 100, remote mesh control device 200, or distributed between mesh installation rig 100 and remote mesh control device 200. Information may be exchanged between remote mesh control device 200 and mesh installation rig 100 over a communication interface including any suitable wireless or wired connection. Examples of suitable communication interfaces are described with reference to FIG. 9.

Mesh controller 114 may be configured to determine and/or maintain the digital meshing plan. The 3D and kinematic model(s) of mesh installation rig 100, or the planned surface model, may be stored at mesh controller 114, for example based on pre-configuration of the model(s) at mesh controller 114. Alternatively, mesh controller 114 may be configured to receive one or more of the models from mesh installation rig 100 or the data management server. Example embodiments of the present disclosure may be thus implemented locally at mesh installation rig 100 and/or at remote mesh control device 200.

FIG. 3 illustrates an example of a data structure of a digital meshing plan. The data structure of a digital meshing plan may comprise a computer-implemented data structure embodied on a computer-readable medium for controlling mesh installation. The data structure may be provided on a memory, such as for example a computer-readable storage medium, examples of which include, but are not limited to, movable storage devices (e.g., universal serial bus stick, compact disc, or the like). Further examples of suitable types of memory for storing the digital meshing plan are described with reference to the at least one memory 904 of FIG. 9.

A data structure digital_meshing_plan may comprise the digital meshing plan. Data structure digital_meshing_plan may be associated with one or more other data structures, such as for example data structure mesh comprising information associated with one mesh (e.g., a single mesh). A data structure may be also called an object, a data object, or an information object. Cardinality between data structures or attributes is represented by values “0”, “1” or “*”. For example, data structure digital_meshing_plan may be associated with one or a plurality of (“1 . . . * ”) data structures mesh, which may comprise or be associated with one attribute planned_mesh_position. Data structure mesh may comprise or be associated with zero or more (“0 . . . * ”) attributes planned_fasterer_position.

Data structure digital_meshing_plan may comprise or be associated with one or more (sub)data structures mesh. Data structure mesh may comprise or be associated with one or more attributes that are related to one mesh. For example, data structure mesh may comprise or be associated with attribute planned_mesh_position, which may be configured to indicate a planned position of a mesh on rock surface 140 for installation of the mesh to rock surface 140 by mesh installation rig 100. The planned position of the mesh may be configured to be indicated with respect to a coordinate frame that is stationary with respect to rock surface 140, e.g., with respect to the coordinate frame of the tunnel (Fₜᵤₙₙₑₗ). The planned position of the mesh may comprise a planned position of least one part (e.g., an edge or corner) of the mesh on rock surface 140. For example, planned positions of two corners of the mesh may be provided to indicate the planned position of the mesh. Alternatively, a planned position of a single point (e.g., a corner) of the mesh may be provided along with a planned orientation of the mesh, in order to indicate the planned position of the mesh. An instance of data structure mesh may comprise or be associated with one attribute planned_mesh_position. The attribute planned_mesh_position may however comprise one or more positions corresponding to different parts of the mesh.

Data structure mesh may comprise or be associated with zero or more (“0 . . . * ”) attributes planned_fastener_position, which may be configured to indicate planned fastener position(s) for installation of the associated mesh to rock surface 140. The planned fastener position(s) may be configured to be indicated with respect to a coordinate frame (e.g., Fₜᵤₙₙₑₗ) that is stationary with respect to rock surface 140, for example the same coordinate frame used for indicating the planned position of the associated mesh.

The planned position of the mesh or the planned fastener position(s) may be provided as a three-dimensional (3D) position(s), which may directly indicate the relevant position at the coordinate frame stationary with respect to rock surface 140. Alternatively, the planned position(s) may be indicated as a two-dimensional (2D) position, for example on a 2D projection of rock surface 140 or as 2D position on a reference plane from which the position is projected to rock surface 140.

An instance of data structure mesh may be identified by a mesh identifier, represented in this example by attribute mesh_id. One mesh may be associated with one mesh identifier (1 . . . 1). A mesh identifier may comprise for example one or more of the following: a serial number, a type identifier (e.g., type number), or a part number of the mesh. A mesh identifier may therefore identify an individual mesh and/or a type of mesh. The mesh identifier may be associated with a planned position of rock surface 140 (e.g., by means of attribute planned_mesh_position). A type identifier may be configured to indicate for example one or more of the following: the shape of mesh eyes (e.g., square or diamond), size of the mesh eyes, a mesh with equal size of mesh eyes, a mesh with different mesh eye size with a particular pattern, material of the mesh (e.g., hot galvanized mesh, stainless mesh, ferritic mesh), size of mesh (e.g., 2270 mm×2530 mm), or the like.

Data structure digital_meshing_plan may comprise or be associated with zero or more (0 . . . *) data structures slot, which may represent a slot (e.g., an area of rock surface 140) for installing a mesh at rock surface 140. A slot may be identified by a slot identifier (e.g., by attribute slot_id). Data structure slot may comprise or be associated with zero or more (0 . . . *) . Data structure slot may comprise or be associated with other properties, such as for example a position of the slot on rock surface 140, or position(s) of mesh to be installed on the slot. For example, attributes planned_mesh_position and/or planned_mounting_position may be associated with a slot (e.g., data structure slot having a particular slot_id). Alternatively, or additionally, attributes of a slot may be configured to indicate an area of rock surface 140 for installing an associated mesh. This may be in addition or alternative to similar attribute(s) being associated with a particular mesh (e.g., data structure mesh having a particular mesh_id). Therefore, the planned position of a mesh or its fastener position(s) may be indicated by attribute(s) of a slot. Mesh controller 114 may be configured to map a particular mesh to a particular slot. Mesh controller 114 may therefore be configured to create an association between a slot and a mesh, as illustrated by the dashed line.

Data structure mesh may comprise or be associated with attributes actual mesh position and/or actual_mounting_position (not shown). This may be the case for example if data structure slot comprises or is associated with attributes planned mesh position and/or planned_mounting_position. Mesh controller 114 may be configured to assign values for actual mesh position and/or actual_mounting_position based on the actual position of the mesh and/or its actual fastener positions, for example subsequent to installation of the mesh on rock surface 140. Even though particular hierarchy of data structures and attributes is illustrated in FIG. 3, it is appreciated that similar functionality and benefits may be provided with other type of structures of the digital_meshing_plan.

Attributes of a particular data structure may include attributes relating to characteristics of the object (e.g., digital or real object) represented by that data structure. For example, attributes of a digital_meshing_plan (e.g., data structure digital_meshing_plan) may include attributes relating to characteristics of the digital_meshing_plan. Attributes of a mesh (e.g., data structure mesh) may include attributes relating to characteristics of the mesh. Attributes of a slot (e.g., data structure slot) may include attributes relating to characteristics of the slot. Such attributes may be referred to as (digital) meshing plan attributes, mesh attributes, or slot attributes, respectively.

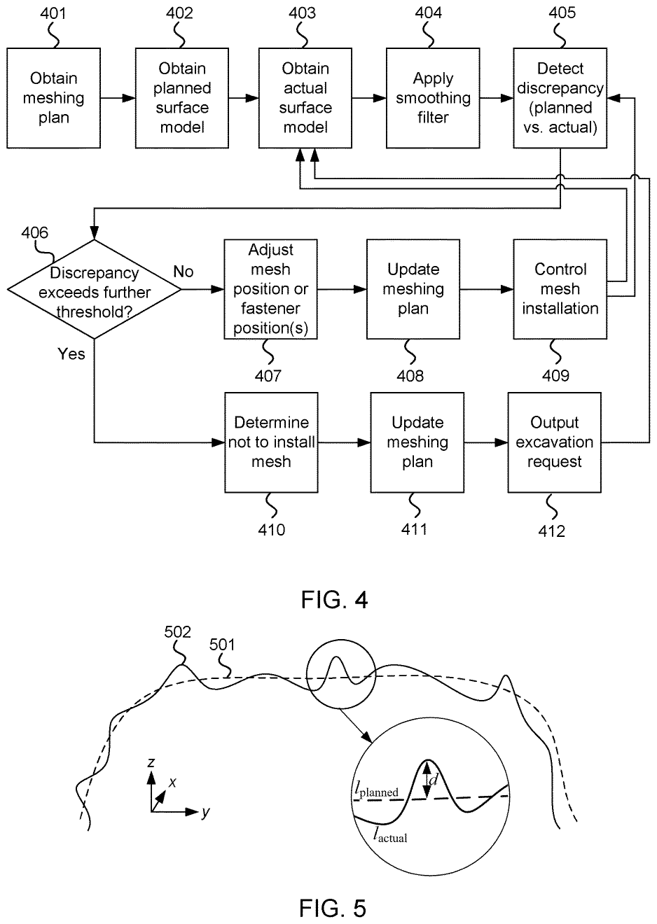

FIG. 4 illustrates an example of a flow chart for controlling mesh installation. Even though operations of the flow chart are described to be performed by mesh controller 114, they may be generally configured to be performed by an apparatus, such as for example mesh installation rig 100, a control apparatus thereof, or remote mesh control device 200.

At operation 401, mesh controller 114 may be configured to obtain a meshing plan, for example as an instance of data structure digital_meshing_plan. The meshing plan may be digital, for example represented as binary digits (bits) or other digital values on a computer-readable memory. The meshing plan may be indicative of planned position(s) of mesh(es) on rock surface 140. The position(s) may be configured for installation of mesh(es) to rock surface 140 by mesh installation rig 100. The planned position(s) of the mesh(es) may be configured to be indicated with respect to coordinate frame Fₜᵤₙₙₑₗ, or in general a coordinate frame that is stationary with respect to rock surface 140. Mesh controller 114 may be configured to obtain information on planned fastener position(s) of the mesh(es), for example as part of the meshing plan.

Mesh controller 114 may be configured to obtain the meshing plan by receiving the meshing plan, for example over an internal communication interface of mesh installation rig 100 or from a device external to mesh installation rig 100 (e.g., remote mesh control device 200). Alternatively, mesh controller 114 may be configured to obtain the meshing plan by retrieving it from at least one memory of an apparatus (e.g., a control apparatus) comprising mesh controller 114, or from at least one memory of mesh installation rig 100. This enables remote and/or local configuration of the digital meshing plan, thereby providing a flexible solution for controlling mesh installation.

Mesh controller 114 may be configured to map the planned position(s) indicated in the meshing plan to a coordinate system of mesh installation rig 100, for example coordinate frame Frig, or in general a coordinate frame that is stationary with respect to mesh installation rig 100. Mesh installation rig 100 may be configured to monitor its location with respect to a coordinate frame (e.g., Fₜᵤₙₙₑₗ) that is stationary with respect to the rock surface 140, for example during navigation in a tunnel. Mesh controller 114 may be configured to determine the planned position(s) with respect to its own coordinate frame (e.g., F_{rig}) based on the current position of mesh installation rig 100 and the planned position(s) indicated in the meshing plan, both with respect to the coordinate frame stationary with respect to rock surface 140. This mapping may be performed for the planned position(s) of the mesh(es) and/or their planned_mounting_position(s). Respectively, mesh controller 114 may be configured to map detected actual positions of mesh(es) or fastener(s) from its own coordinate frame to the coordinate frame stationary with respect to rock surface 140.

At operation 402, mesh controller 114 may be configured to obtain a planned surface model of rock surface 140. Mesh controller 114 may be for example configured to determine the planned surface model from the meshing plan obtained at operation 401, receive the meshing plan, for example over an internal communication interface of mesh installation rig 100 or from a device external to mesh installation rig 100 (e.g., remote mesh control device 200), or retrieve the planned surface model from at least one memory of an apparatus (e.g., a control apparatus) comprising mesh controller 114 or from at least one memory of mesh installation rig 100. Mesh controller 114 may be configured to map points of the planned surface model from the coordinate frame stationary with respect to rock surface 140 to coordinate system of mesh installation rig 100, for example similar to mapping of the planned positions of the meshing plan, as described above.

At operation 403, mesh controller 114 may be configured to obtain an actual surface model of rock surface 140. The actual surface model may correspond to the in situ rock surface 140 observable by mesh installation rig 100, for example in a particular position of mesh installation rig 100 in the tunnel, prior to or during mesh installation. The actual surface model may be based on scanning data of rock surface 140. Mesh installation rig 100, or in general any other scanning device, may be configured to scan rock surface 140, for example as described above, to obtain scanning data indicative of the geometry of rock surface 140. Mesh controller 114 may be configured to cause the scanning, for example by instructing mesh installation rig 100 to perform the scanning. Mesh controller 114 may be configured to receive the scanning data from the scanning device.

At operation 404, mesh controller 114 may be configured to apply a smoothing filter, e.g., a Gaussian blur filter, on the scanning data. Mesh controller 114 may be configured to apply the smoothing filter on the scanning data. A smoothing filter may be configured to act as a low pass filter that smoothens geometrical variations in the surface model to a desired extent. This enables to simulate how a mesh would be deformed when installing it on rock surface 140. For example, very steep variations in the actual rock surface may be ignored when determining whether discrepancies between the planned and actual surface models are to be considered in meshing. It is however noted that example embodiments may be alternatively applied on raw scanning data or that a smoothing filter may be applied on the scanning data before mesh controller 114 receives the scanning data, for example at the scanning device such as for example sensor 112.

At operation 405, mesh controller 114 may be configured to detect a discrepancy between the planned and actual surface models of rock surface 140. Mesh controller 114 may be configured to detect the discrepancy for example based on a difference in lengths of respective curves on the planned and actual surface models, and/or based on a distance between the respective curves on the planned and actual surface models. Examples of these two approaches are illustrated in FIG. 5, where planned surface model 501 is illustrated by the dashed line and actual surface model 502 is illustrated by the solid line. In this example, the planned and actual surface models are illustrated by a two-dimensional tunnel profile on the yz-plane at certain position along axis x. It is however noted that planned surface model 501 and actual surface model 502 may comprise 3D surfaces extending also in the direction of axis x. An enlargement of the circled portion of the planned and actual surface models 501, 502 is also illustrated. This portion may correspond to planned position(s) of one or more meshes or one or more slots of the meshing plan. Mesh controller 114 may be configured to update the meshing plan based on the detected discrepancy, as will be further explained for example with reference to operations 407, 408, 410, and 411.

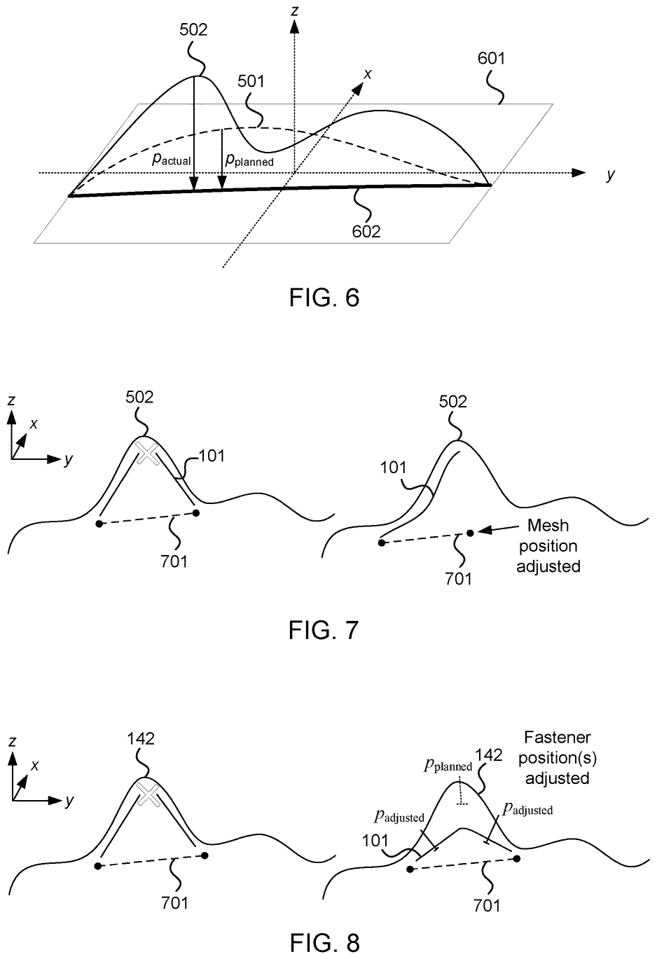

Mesh controller 114 may be configured to detect the discrepancy between planned and actual surface models 501, 502 based on comparing lengths (l_{planned}, l_{actual}) to a first threshold. Mesh controller 114 may be configured to detect the discrepancy (e.g., determine that there exists a discrepancy that is to be considered in meshing), in response to determining that the difference in lengths of the respective curves on the planned and actual surface models 501, 502 exceeds the first threshold. Mesh controller 114 may be configured to calculate the lengths of the respective curves based on geometry of the planned and actual surface models 501, 502, for example at the targeted position of mesh 101 or the slot. The respective curves may correspond to curves between two points of each surface model, where the curves substantially overlap when viewed perpendicularly towards rock surface 140 or the planned or actual surface models 501, 502. In other words, projections of the respective curves to a planar projection of rock surface may result in substantially identical lines, as will be further explained with reference to FIG. 6. In this context, term ‘substantially’ may be understood such that the substantially overlapping or identical lines enable a meaningful comparison between profiles of the planned and actual surface models 501, 502, in order to determine whether discrepancy of the planned and actual surface models 501, 502 is to be considered when meshing rock surface 140. Examples of the respective curves are the two-dimensional representations of the planned and actual surface models 501, 502 at the yz-plane, as illustrated in FIG. 5.

Alternatively, or additionally, mesh controller 114 may be configured to detect the discrepancy based on distance between the respective curves on the planned and actual surface models 501, 502. Mesh controller 114 may be configured to detect the discrepancy (e.g., determine that there exists a discrepancy that is to be considered in meshing), in response to determining that the distance (d) between the respective curves on the planned and actual surface models 501, 502 exceeds a second threshold, for example at any location of one of the curves. Mesh controller 114 may be configured to calculate the distance between the respective curves based on geometry of the planned and actual surface models 501, 502, for example at the targeted position of mesh 101 or the associated slot.

Mesh controller 114 may be configured to detect the discrepancy either based on the condition on the lengths of the respective curves or their distance (e.g., the first or second threshold), or in response to determining both conditions to be fulfilled. In both cases, applying the smoothing filter provides the benefit of avoiding false alarms for detecting the discrepancy. For example, detecting a discrepancy due to a very steep recess in rock surface 140, which would not require any change to meshing because the mesh would just easily bridge the steep recess, may be avoided.

FIG. 6 illustrates an example of projection of respective curves of the planned and actual surface model on a planar projection of the rock surface. Planar projection 601 of rock surface 140 may comprise a plane to which points of rock surface 140 are projected. For example, when considering the roof (horizontal surface) of the tunnel, the planar projection of rock surface 140 may be an xy-plane at certain position of axis z. When considering a wall (vertical surface) of the tunnel, the planar projection of rock surface 140 may be an xz-plane at certain position of axis y. When considering non-horizonal and non-vertical portions of rock surface, the planar projection may be a plane that has certain inclination from the xy-plane around axis x and certain position along axis z. Such an artificial projection plane may be used to characterize the respective curves of the planned and actual surface models 501, 502. Considering the example of FIG. 6, (perpendicular) projections (p_{planned}, p_{actual}) of the respective curves of the planned and actual surface models 501, 502 to planar projection 601 of rock surface 140 yield identical (straight) lines 602. This guarantees that the lengths of these curves, or distance therebetween, can be meaningfully compared, in order to detect a discrepancy between the planned and actual surface models. Depending on the geometry of the planned and/or actual surface models 501, 502, the respective curves may provide the shortest path between two respective points at each plane. In the simplified example of FIG. 6, the starting points of the respective curves coincide at the planar projection 601, but this need not be the case.

It is noted that when determining whether there is a discrepancy, mesh controller 114 may be configured to perform the above evaluation for one or more curves of the planned and actual surface models 501, 502, for example in order to cover a surface area that is to be covered by one or more meshes or, e.g., one or more slots of the meshing plan. For example, mesh controller 114 may be configured to determine that there is a discrepancy, if the condition (e.g., first or second threshold) is fulfilled for at least one pair of respective curves on the planned and actual surface models 501, 502. Hence, mesh controller 114 may be configured to detect the discrepancy, in response to determining that a difference in lengths of at least one pair of respective curves, among a plurality of pairs of respective curves, on the planned and actual surface models 501, 502 exceeds the first threshold. Alternatively, or additionally, mesh controller 114 may be configured to detect the discrepancy, in response to determining that a distance between at least one pair of the respective curves, among a plurality of pairs of respective curves, on the planned and actual surface models 501, 502 exceeds the second threshold. It is however understood that various other conditions may be formulated when using multiple pairs of respective curves, e.g., their average difference in length or their average distance. In general, mesh controller 114 may be configured to detect the discrepancy based on the plurality of pairs of respective curves on the planned and actual surface models 501, 502.

Referring back to FIG. 4, at operation 406 mesh controller 114 may be configured to determine whether the detected discrepancy is exceeds a further threshold (e.g., third or fourth threshold). This enables mesh controller 114 to determine whether the discrepancy is to be handled by adjusting mesh position or fastener position(s), or whether the mesh is not to be installed on the planned position. Mesh controller 114 may be configured to move to execution of operation 407, in response to determining that the discrepancy does not exceed the further threshold. Mesh controller 114 may be configured to move to execution of operation 410, in response to determining that the discrepancy does not exceed the further threshold.

At operation 407, mesh controller 114 may be configured to adjust mesh position or fastener position(s) based on the detected discrepancy. Mesh controller 114 may be configured to adjust the planned position of mesh 101 to cause an edge of mesh 101 to substantially coincide with a recess of rock surface 140. An example of this is provided in FIG. 7. If mesh 101 were installed on its originally planned position 701, mesh 101 might break when mounted at a recess of rock surface 140 reflected in actual surface model 502, as illustrated on the left. As illustrated on the right, planned mesh position 701 may be adjusted to the left such that an edge of mesh 101 substantially coincides with the recess. This provides the benefit of enabling mesh 101 to be installed on rock surface 140 without bending mesh 101 at the bottom of the recess, and thereby to reduce the risk of breakage. Mesh controller 114 may be configured to determine the position of the recess based on geometry of actual surface model 502. Substantially coinciding may correspond to aligning the edge of mesh 101 with the recess such that bending at the bottom of the recess is avoided, or at least reduced to the extent that breakage of mesh 101 may be avoided.

Alternatively, or additionally, mesh controller 114 may be configured to adjust the planned position of adjacent mesh(es) indicated in the meshing plan to cause the edge of mesh 101 to overlap with the adjacent mesh(es). This provides the benefit of enabling a desired area of rock surface 140 to be covered by the meshes. Mesh controller 114 may be configured to determine position(s) of adjacent mesh(es), or edge(s) thereof, based on scanning data received from sensor 112, e.g., by means of a computer vision algorithm configured to be executed on visual data received from a camera.

Alternatively, or additionally, mesh controller 114 may be configured to adjust the planned fastener position(s) away from a recess of rock surface 140, for example to cause the fastener(s) not to coincide with the recess of rock surface 140. An example of this is provided in FIG. 8. As illustrated on the right, planned fastener position (p_{planned}) may be adjusted to the left and/or right (p_{adjusted}) such that mesh 101 is not fastened at the bottom of the recess. This provides the benefit of enabling mesh 101 to be installed on rock surface 140 without causing excessive bending, possibly a breakage, at the position of the recess. For example, this enables mesh 101 to be installed such that it bridges the recess and it is fastened to rock surface 140 at two sides of the recess. Adjusting fastener positions may comprise increasing or reducing the number of fastener positions.

Mesh controller 114 may be configured to adjust the planned position of mesh 101 based on the difference in the lengths of the respective curves on the planned and actual surface model 501, 502. For example, mesh controller 114 may be configured to adjust the planned position of mesh 101 (e.g., its centre position) such that one edge of mesh 101 is configured to maintain the originally planned position while another edge is configured to be shifted. Mesh controller 114 may be further configured to adjust the position of the adjacent mesh(es) such that they overlap with the shifted edge of mesh 101. This provides the benefit of enabling to take into account discrepancies between the planned and actual surface models 501, 502 and to control mesh installation such that the desired area of rock surface 140 is fully covered by the meshes without any gaps.

At operation 408, mesh controller 114 may be configured to update the meshing plan with the adjusted mesh position(s) and/or fastener position(s). For example, mesh controller 114 may be configured to change value(s) of attribute(s) planned_mesh_position or planned_fastener_position of data structure mesh corresponding to mesh 101. This provides the benefit of maintaining up-to-date information about the current status of the meshing plan and installation of meshes at their adjusted positions and/or with the adjusted fastener positions. However, updating the meshing plan may generally comprise any operation configured to record the information about the adjusted mesh position(s) or fastener position(s), regardless of whether such update is recorded within the original meshing plan. For example, such updates position information could be stored separately from the original data structure digital_meshing_plan.

At operation 409, mesh controller 114 may be configured to control mesh installation based on the updated meshing plan. For example, mesh controller 114 may be configured to control installation of the mesh(es) to rock surface 140 based on the planned position of the mesh(es) obtained based on the digital meshing plan and/or as adjusted by mesh controller 114. Mesh controller 114 may be configured to control fastening of the mesh(es) to rock surface 140 based on the planned fastener position(s), for example as indicated in the digital meshing plan and/or as adjusted by mesh controller 114.

Controlling mesh installation may comprise controlling positioning of mesh 101 for installation at rock surface 140. For example, mesh controller 114 may be configured to control movement at least one boom, for example boom 120-1 comprising gripper 124, to position mesh 101 for being installed on rock surface 140. Mesh controller 114 may be configured to determine the position of the mesh 101 based on the updated digital meshing plan, or in general the adjusted mesh position and/or adjusted fastener position(s).

Controlling mesh installation may comprise controlling fastening mesh 101 to rock surface 140. Controlling the fastening of mesh 101 may comprise causing mesh installation rig 100 to fasten mesh 101 at rock surface 140 with fastener(s). Controlling fastening of mesh 101 may comprise determining an order of fastener positions or a fastening rate (e.g., in bolts/min). Controlling fastening of mesh 101 may comprise causing mesh installation rig 100 to fasten mesh 101 to rock surface 140 according to the determined order of fastener positions or the fastening rate. Controlling fastening of mesh 101 may comprise controlling movement of at least one boom, for example boom 120-2 comprising bolter 126, to cause mounting of mesh 101 to rock surface 140.

Controlling mesh installation may therefore comprise controlling movement of at least one boom, for example booms 120-1, 120-2 and their respective tools, to cause both placement of mesh 101 at rock surface 140 and fastening of mesh 101 at rock surface 140 at this position. Controlling mesh installation may comprise providing control instructions, e.g., to a kinematic controller of mesh installation rig 100, that cause the desired movement of the boom(s) and tool(s). Controlling mesh installation may further comprise controlling collision avoidance, for example when moving mesh 101 with boom 120-1 and gripper 124 or when moving bolter 126 for mounting mesh 101. Mesh controller 114, or mesh installation rig 100, may be configured to perform collision avoidance to avoid collisions between component(s) of mesh installation rig 100 (e.g., boom 120-1, boom 120-2, gripper 124, bolter 126, or movable carrier 110), mesh 101, or rock surface 140. Collision avoidance may be based on the kinematic model of mesh installation rig 100. When the procedure of FIG. 4 is performed by mesh installation rig 100, mesh installation rig 100 may perform the mesh installation.

Mesh controller 114 may be configured to detect an error associated with installation of mesh 101, in response to detecting, subsequent to installation of the mesh 101 on rock surface 140, that mesh 602 does not overlap adjacent mesh(es). Mesh controller 114 may be configured to update the meshing plan by configuring additional mesh(es) to be installed between mesh 101 and the adjacent mesh(es) on the area where mesh 101 does not overlap with the adjacent mesh(es), e.g., when viewed perpendicularly towards rock surface 140. This provides the benefit of enabling the desired area of rock surface 140 to be covered regardless of positioning errors occurring during the mesh installation.

Mesh controller 114 may be configured to move back to execution of operation 403 or 405, depending on whether the area to be covered by the next mesh (e.g., next slot) is included in actual surface model 502 obtained at operation 403. Mesh controller 114 may be configured to move to operation 405 if the area is already included in actual surface model 502. Mesh controller 114 may be then configured to determine whether a discrepancy between the planned and actual surface models 501, 502 exist at the area of rock surface 140 targeted for the next mesh. If the area to be covered by the next mesh is not included in actual surface model 502, mesh controller 114 may be configured to move to execution of operation 403 to obtain the actual surface model for the area targeted for the next mesh.

At operation 410, mesh controller 114 may determine not to install mesh 101 at the planned position, in response to determining (cf. operation 406) that the discrepancy exceeds the further threshold. For example, mesh controller 114 may be configured to determine not to install mesh 101 at the planned position, in response to determining that the difference in lengths of the respective curves on the planned and actual surface models 501, 502 exceeds the third threshold. The third threshold may be higher than the first threshold, which may be used at operation 405 for detecting existence of the discrepancy based on lengths of the respective curves. Alternatively, or additionally, mesh controller 114 may be configured to determine not to install mesh 101 at the planned position, in response to determining that the distance between the respective curves on the planned and actual surface model 501, 502 exceeds the fourth threshold. The fourth threshold may be higher than the second threshold, which may be used at operation 405 for detecting existence of the discrepancy based on the distance between the respective curves. The thresholds may be applied to a plurality of pairs of respective curves, as described with reference to operation 405. Operation 410 provides the benefit of avoiding installation of mesh 101 at a position, where rock surface 140 is too rough for successful mesh installation. Any of the thresholds may be pre-configured at mesh controller 114, or received by mesh controller 114, for example over an internal communication interface of mesh installation rig 100 or from a device external to mesh installation rig 100 (e.g., remote mesh control device 200). The threshold(s) may be received for example as part of the meshing plan. The threshold(s) may be associated with particular mesh(es), e.g., by means of mesh_id, or a type of mesh. This provides the benefit of enabling adaptation of the meshing plan based on physical properties (e.g., strength) of a particular (type of) mesh. For example, higher discrepancy threshold(s) may be applied for relatively stronger meshes and lower discrepancy threshold(s) may be applied for relatively weaker meshes.

At operation 411, mesh controller 114 may be configured to update the meshing plan by configuring mesh 101 not to be installed on its planned position. This provides the benefit of enabling to keep track of positions where a mesh can not be installed without further actions, such as for example further excavation.

At operation 412, mesh controller 114 may be configured to output a request for further excavation of rock surface 140 at the planned position of mesh 101. The output may be provided for example by transmitting an excavation request message, for example over an internal communication interface of mesh installation rig 100 or to a device external to the mesh installation rig (e.g., remote mesh control device 200). The excavation request may comprise an indication of the planned position of the mesh that was determined not to be installed. Subject to further excavation, this enables mesh 101 to be installed at a position, where rock surface 140 was initially too rough. Mesh controller 114 may be configured to move from execution of operation 412 to execution of operation 403 to obtain an updated actual surface model of rock surface 140 subsequent to the further excavation. After the further excavation it is more likely that mesh 101 can be installed on the planned position, optionally after adjustment of the mesh position or fastener position(s) at subsequent execution of operation 407.

Even though particular sequence of operations is illustrated in FIG. 4, it is understood that the operations may be executed in any suitable order and that some operations might not be present in all example embodiments. For example, application of the smoothing filter (operation 404) and outputting the excavation request (operation 412) may be optional. Furthermore, the procedure of FIG. 4 may be iterated for multiple meshes or individual operations may be performed for multiple meshes in one go, e.g., sequentially or in parallel.

Mesh controller 114 may be further configured to transmit feedback, for example indication(s) of actual position(s) of mesh(es) installed on rock surface 140 and/or their fastener position(s). Mesh controller 114 may be for example configured to determine the actual position of mesh 101 on rock surface 140 after installation of mesh 101. Mesh controller 114 may be configured to determine the actual position of mesh 101 based on the actual fastener position(s) used for fastening mesh 101 on rock surface 140. Mesh controller 114 may be configured to determine the actual position or actual fastener position(s) of mesh 101 based on the adjusted position(s) determined at operation 407 or based on monitoring location and/or orientation of gripper 124 and/or a mounting tool (e.g., bolter 126) when installing mesh 101 on rock surface 140. Alternatively, or additionally, mesh controller 114 may be configured to control scanning of rock surface 140 by sensor 112, in order to detect mesh 101. Mesh controller 114 may be configured to determine the actual position of mesh 101 based on scanning data of sensor 112. Mesh controller 114 may be configured to store actual position and/or actual mounting position(s) of mesh 101, for example in the digital meshing plan (e.g., as attributes actual_mesh_position and/or actual_mounting_position of associated with data structure mesh).

Mesh controller 114 may be configured to transmit an indication of the actual position of mesh(es) installed on rock surface 140, for example over an internal communication interface of mesh installation rig 100 or to a device external to the mesh installation rig (e.g., remote mesh control device 200). Mesh controller 114 may be configured to transmit as feedback indication(s) of other parameter(s) associated with installing the meshes included in the digital meshing plan, for example indication(s) of actual fastener position(s). The feedback may be provided as an updated instance of the meshing plan.

FIG. 9 illustrates an example of an apparatus configured to practise one or more example embodiments. Apparatus 900 may be or comprise a mesh control apparatus, such as for example a server, communicatively coupled to mesh installation rig 100, a mesh control apparatus located at mesh installation rig 100, mesh controller 114, mesh installation rig 100 itself, or in general any device or system configured to implement the functionality described herein. Although apparatus 900 is illustrated as a single device, it is appreciated that, wherever applicable, functions of apparatus 900 may be distributed to a plurality of devices.

Apparatus 900 may comprise at least one processor 902. The at least one processor 902 may comprise, for example, one or more of various processing devices, such as for example a co-processor, a microprocessor, a controller, a digital signal processor (DSP), a processing circuitry with or without an accompanying DSP, or various other processing devices including integrated circuits such as, for example, an application specific integrated circuit (ASIC), a field programmable gate array (FPGA), a microcontroller unit (MCU), a hardware accelerator, a special-purpose computer chip, or the like.

Apparatus 900 may further comprise at least one memory 904. The at least one memory 904 may be configured to store, for example, computer program code or the like, for example operating system software and application software. The at least one memory 904 may comprise one or more volatile memory devices, one or more non-volatile memory devices, and/or a combination thereof. For example, the memory may be embodied as magnetic storage devices (such as hard disk drives, etc.), optical magnetic storage devices, or semiconductor memories (such as mask ROM, PROM (programmable ROM), EPROM (erasable PROM), flash ROM, RAM (random access memory), etc.). Memory 904 is provided as an example of a (non-transitory) computer readable medium. The term “non-transitory,” as used herein, is a limitation of the medium itself (i.e., tangible, not a signal) as opposed to a limitation on data storage persistency (e.g., RAM vs. ROM). The at least one memory 904 may be also embodied separate from apparatus 900, for example as a computer readable (storage) medium, examples of which include memory sticks, compact discs (CD), or the like.

When apparatus 900 is configured to implement some functionality, some component and/or components of apparatus 900, such as for example the at least one processor 902 and/or the at least one memory 904, may be configured to implement this functionality. Furthermore, when the at least one processor 902 is configured to implement some functionality, this functionality may be implemented using program code 906 comprised, for example, in the at least one memory 904.

The functionality described herein may be performed, at least in part, by one or more computer program product components such as software components. According to an example embodiment, apparatus 900 comprises a processor or processor circuitry, such as for example a microcontroller, configured by the program code 906, when executed, to execute the embodiments of the operations and functionality described herein. Program code 906 is provided as an example of instructions which, when executed by the at least one processor 902, cause performance of apparatus 900.

For example, mesh controller 114 may be at least partially implemented as program code configured to cause apparatus 900 to perform functionality of mesh controller 114. Similarly, transmission or reception of data (e.g. sensor data, kinematic model(s), or the digital meshing plan) over an internal or external communication interface of mesh installation rig 100 may be controlled by software.

Alternatively, or in addition, the functionality described herein can be performed, at least in part, by one or more hardware logic components. For example, and without limitation, illustrative types of hardware logic components that can be used include field-programmable gate arrays (FPGAs), application-specific integrated circuits (ASICs), application-specific standard products (ASSPs), system-on-a-chip systems (SOCs), complex programmable logic devices (CPLDs), graphics processing units (GPUs), neural processing unit (NPU), tensor processing unit (TPU), or the like.

Apparatus 900 may comprise a communication interface 908 configured to enable apparatus 900 to transmit and/or receive information. Communication interface 908 may comprise an internal or external communication interface, such as for example a radio interface between mesh installation rig 100 and remote mesh control device 200 or an internal control bus within mesh installation rig. Apparatus 900 may further comprise other components and/or functions such as for example a user interface (not shown) comprising at least one input device and/or at least one output device. The input device may take various forms such as a keyboard, a touch screen, or one or more embedded control buttons. The output device may for example comprise a display, a speaker, or the like. The user interface may enable a human operator to monitor various functions and data, such as for example the digital meshing plan, or the like.

Apparatus 900 may be configured to perform or cause performance of any aspect of the method(s) described herein. Further, a computer program or a computer program product may comprise instructions for causing, when executed by apparatus 900, apparatus 900 to perform any aspect of the method(s) described herein. Further, apparatus 900 may comprise means for performing any aspect of the method(s) described herein. In one example, the means comprises the at least one processor 902, the at least one memory 904 including program code 906 (instructions) configured to, when executed by the at least one processor 902, cause apparatus 900 to perform the method(s). In general, computer program instructions may be executed on means providing generic processing functions. Such means may be embedded for example in a computer, a server, or the like. The method(s) may be thus computer-implemented, for example based algorithm(s) executable by the generic processing functions, an example of which is the at least one processor 902. Apparatus 900 may comprise means for transmitting or receiving information, for example one or more wired of wireless (e.g. radio) transmitters or receivers, which may be coupled or be configured to be coupled to one or more antennas, or transmitter(s) or receiver(s) of a wired communication interface.

According to a first aspect, an apparatus for controlling mesh installation is disclosed. The apparatus may comprise: at least one processor; and at least one memory including computer program code, the at least one memory and the computer program code configured to, with the at least one processor, cause the apparatus at least to: obtain a meshing plan indicative of at least one of: a planned position of at least one mesh for installation of the at least one mesh to a rock surface, or a planned position of at least one fastener for fastening the at least one mesh to the rock surface; obtain a planned surface model of the rock surface; obtain an actual surface model of the rock surface; detect a discrepancy between the planned surface model and the actual surface model; update the meshing plan based on the detected discrepancy; and/or control the mesh installation based on the updated meshing plan.

According to an example embodiment of the first aspect, the actual surface model is based on scanning data of the rock surface.

According to an example embodiment of the first aspect, the computer program code is further configured to, with the at least one processor, cause the apparatus to: update the meshing plan by adjusting at least one of the planned position of the at least one mesh or the planned position of the at least one fastener based on the detected discrepancy; and control installation of the at least one mesh to the rock surface based on the adjusted position of the at least one mesh or the at least one fastener.

According to an example embodiment of the first aspect, the computer program code is further configured to, with the at least one processor, cause the apparatus to: detect the discrepancy, in response to determining that a difference in lengths of respective curves on the planned surface model and the actual surface model exceeds a first threshold.

According to an example embodiment of the first aspect, the computer program code is further configured to, with the at least one processor, cause the apparatus to: detect the discrepancy, in response to determining a distance between respective curves on the planned surface model and the scanned actual surface model to exceed a second threshold.

According to an example embodiment of the first aspect, projections of the respective curves to a planar projection of the rock surface comprise substantially identical lines.

According to an example embodiment of the first aspect, the computer program code is further configured to, with the at least one processor, cause the apparatus to: update the meshing plan by configuring the at least one mesh not to be installed on the planned position of the at least one mesh, in response to determining the difference in the lengths of the respective curves on the planned surface model and the actual surface model to exceed a third threshold, or in response to determining the distance between the respective curves on the planned surface model and the actual surface model to exceed a fourth threshold, wherein the third threshold is higher than the first threshold and the fourth threshold is higher than the second threshold.

According to an example embodiment of the first aspect, the computer program code is further configured to, with the at least one processor, cause the apparatus to: output a request for further excavation of the rock surface at the planned position of the at least one mesh.

According to an example embodiment of the first aspect, the computer program code is further configured to, with the at least one processor, cause the apparatus to: adjust the planned position of the at least one mesh to cause an edge of the at least one mesh to coincide with a recess of the rock surface, adjust a planned position of at least one adjacent mesh indicated in the meshing plan to cause the edge of the at least one mesh to overlap with the at least one adjacent mesh, or adjust the planned position of the at least one fastener to cause the at least one fastener not to coincide with the recess of the rock surface.

According to an example embodiment of the first aspect, the planned position of the adjacent mesh is configured to be adjusted based on the difference in the lengths of the respective curves on the planned surface model and the actual surface model.

According to an example embodiment of the first aspect, the computer program code is further configured to, with the at least one processor, cause the apparatus to: detect an error associated with installation of the at least one mesh, in response to detecting, subsequent to installation of the at least one mesh on the rock surface, the at least one mesh not to overlap with at least one adjacent mesh; and update the meshing plan by configuring at least one additional mesh to be installed between the at least one mesh and the at least one adjacent mesh.

According to an example embodiment of the first aspect, the computer program code is further configured to, with the at least one processor, cause the apparatus to: apply a smoothing filter on the scanning data to obtain the actual surface model.

According to an example embodiment of the first aspect, the computer program code is further configured to, with the at least one processor, cause the apparatus to: obtain the scanning data from at least one of the following: a camera, a radio detection and ranging sensor, a light detection and ranging sensor laser, or a device configured to physically probe the rock surface.

According to a second aspect, a mesh installation rig is disclosed. The mesh installation rig may comprise the apparatus according to any example embodiment of the first aspect.

FIG. 10 illustrates an example of a method for controlling mesh installation, according to a third aspect of the present disclosure. The method may comprise a computer-implemented method performed by, for example, apparatus 900 such as mesh controller 114.

At 1001, the method may comprise obtaining a meshing plan indicative of at least one of: a planned position of at least one mesh for installation of the at least one mesh to a rock surface, or a planned position of at least one fastener for fastening the at least one mesh to the rock surface.

At 1002, the method may comprise obtaining a planned surface model of the rock surface.

At 1003, the method may comprise obtaining an actual surface model of the rock surface.

At 1004, the method may comprise detecting a discrepancy between the planned surface model and the actual surface model.

At 1005, the method may comprise updating the meshing plan based on the detected discrepancy.

At 1006, the method may comprise controlling the mesh installation based on the updated meshing plan.

The method may be performed by mesh controller 114, mesh installation rig 100, or remote mesh control device 200, for example based on program code 906, when executed by processor 902. Various examples of the methods are explained above with regard to functionalities of mesh controller 114, mesh installation rig 100, and/or remote mesh control device 200, in addition to the example embodiments listed below. It should be understood that example embodiments described may be combined in different ways unless explicitly disallowed.

According to an example embodiment of the third aspect, the actual surface model is based on scanning data of the rock surface.

According to an example embodiment of the third aspect, the method comprises: updating the meshing plan by adjusting at least one of the planned position of the at least one mesh or the planned position of the at least one fastener based on the detected discrepancy; and controlling installation of the at least one mesh to the rock surface based on the adjusted position of the at least one mesh or the at least one fastener.

According to an example embodiment of the third aspect, the method comprises: detecting the discrepancy, in response to determining that a difference in lengths of respective curves on the planned surface model and the actual surface model exceeds a first threshold.

According to an example embodiment of the third aspect, the method comprises: detecting the discrepancy, in response to determining a distance between respective curves on the planned surface model and the scanned actual surface model to exceed a second threshold.

According to an example embodiment of the third aspect, projections of the respective curves to a planar projection of the rock surface comprise substantially identical lines.

According to an example embodiment of the third aspect, the method comprises: updating the meshing plan by configuring the at least one mesh not to be installed on the planned position of the at least one mesh, in response to determining the difference in the lengths of the respective curves on the planned surface model and the actual surface model to exceed a third threshold, or in response to determining the distance between the respective curves on the planned surface model and the actual surface model to exceed a fourth threshold, wherein the third threshold is higher than the first threshold and the fourth threshold is higher than the second threshold.

According to an example embodiment of the third aspect, the method comprises: outputting a request for further excavation of the rock surface at the planned position of the at least one mesh.

According to an example embodiment of the third aspect, the method comprises: adjusting the planned position of the at least one mesh to cause an edge of the at least one mesh to coincide with a recess of the rock surface, adjusting a planned position of at least one adjacent mesh indicated in the meshing plan to cause the edge of the at least one mesh to overlap with the at least one adjacent mesh, or adjusting the planned position of the at least one fastener to cause the at least one fastener not to coincide with the recess of the rock surface.

According to an example embodiment of the third aspect, the method comprises: adjusting the planned position of the adjacent mesh based on the difference in the lengths of the respective curves on the planned surface model and the actual surface model.

According to an example embodiment of the third aspect, the method comprises: detecting an error associated with installation of the at least one mesh, in response to detecting, subsequent to installation of the at least one mesh on the rock surface, the at least one mesh not to overlap with at least one adjacent mesh; and updating the meshing plan by configuring at least one additional mesh to be installed between the at least one mesh and the at least one adjacent mesh.

According to an example embodiment of the third aspect, the method comprises: applying a smoothing filter on the scanning data to obtain the actual surface model.

According to an example embodiment of the third aspect, the method comprises: obtaining the scanning data from at least one of the following: a camera, a radio detection and ranging sensor, a light detection and ranging sensor laser, or a device configured to physically probe the rock surface.

According to an example embodiment of the third aspect, the method may be performed by the mesh installation rig.

According to a fourth aspect, an apparatus may comprise means for performing the method according to the third aspect, or any example embodiment(s) thereof.

According to a fifth aspect, a computer program, a computer program product, or a (non-transitory) computer-readable medium may comprise instructions which, when executed by an apparatus, cause the apparatus at least to perform the method according to the third aspect, or any example embodiment(s) thereof.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

The steps or operations of the methods described herein may be carried out in any suitable order, or simultaneously where appropriate. Additionally, individual blocks may be deleted from any of the methods without departing from the scope of the subject matter described herein. Aspects of any of the example embodiments described above may be combined with aspects of any of the other example embodiments described to form further example embodiments without losing the effect sought.

The term ‘comprising’ is used herein to mean including the method, blocks, or elements identified, but that such blocks or elements do not comprise an exclusive list and a method or apparatus may contain additional blocks or elements.

As used herein, “at least one of the following: <a list of two or more elements>” and “at least one of <a list of two or more elements>” and similar wording, where the list of two or more elements are joined by “and” or “or”, mean at least any one of the elements, or at least any two or more of the elements, or at least all the elements. Term “or” may be understood to also cover a case where both of the items separated by “or” are included. Hence, “or” may be understood as an inclusive “or” rather than an exclusive “or”.

Although subjects may be referred to as ‘first’ or ‘second’ subjects, this does not necessarily indicate any order or importance of the subjects. Instead, such attributes may be used solely for the purpose of making a difference between subjects.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from scope of this specification.

1. An apparatus for controlling mesh installation, the apparatus comprising:
at least one processor; and
at least one memory including computer program code, the at least one memory and the computer program code configured to, with the at least one processor, cause the apparatus at least to:
obtain a meshing plan indicative of at least one of a planned position of at least one mesh for installation of the at least one mesh to a rock surface, or a planned position of at least one fastener for fastening the at least one mesh to the rock surface;
obtain a planned surface model of the rock surface;
obtain an actual surface model of the rock surface;
detect a discrepancy between the planned surface model and the actual surface model;
update the meshing plan based on the detected discrepancy; and
control the mesh installation based on the updated meshing plan.

2. The apparatus according to claim 1, wherein the actual surface model is based on scanning data of the rock surface.

3. The apparatus according to claim 1, wherein the computer program code is further configured to, with the at least one processor, cause the apparatus to:
update the meshing plan by adjusting at least one of the planned position of the at least one mesh or the planned position of the at least one fastener based on the detected discrepancy; and
control installation of the at least one mesh to the rock surface based on the adjusted position of the at least one mesh or the at least one fastener.

4. The apparatus according to claim 1, wherein the computer program code is further configured to, with the at least one processor, cause the apparatus to:
detect the discrepancy, in response to determining that a difference in lengths of respective curves on the planned surface model and the actual surface model exceeds a first threshold.

5. The apparatus according to claim 1, wherein the computer program code is further configured to, with the at least one processor, cause the apparatus to:
detect the discrepancy, in response to determining a distance between respective curves on the planned surface model and the actual surface model to exceed a second threshold.

6. The apparatus according to claim 5, wherein projections of the respective curves to a planar projection of the rock surface comprise substantially identical lines.

7. The apparatus according to claim 4, wherein the computer program code is further configured to, with the at least one processor, cause the apparatus to:
update the meshing plan by configuring the at least one mesh not to be installed on the planned position of the at least one mesh, in response to determining the difference in the lengths of the respective curves on the planned surface model and the actual surface model to exceed a third threshold, or in response to determining the distance between the respective curves on the planned surface model and the actual surface model to exceed a fourth threshold, wherein the third threshold is higher than the first threshold and the fourth threshold is higher than the second threshold.

8. The apparatus according to claim 7, wherein the computer program code is further configured to, with the at least one processor, cause the apparatus to:
output a request for further excavation of the rock surface at the planned position of the at least one mesh.

9. The apparatus according to claim 1, wherein the computer program code is further configured to, with the at least one processor, cause the apparatus to:
adjust the planned position of the at least one mesh to cause an edge of the at least one mesh to coincide with a recess of the rock surface, adjust a planned position of at least one adjacent mesh indicated in the meshing plan to cause the edge of the at least one mesh to overlap with the at least one adjacent mesh, or adjust the planned position of the at least one fastener to cause the at least one fastener not to coincide with the recess of the rock surface.

10. The apparatus according to claim 4, wherein the planned position of the adjacent mesh is configured to be adjusted based on the difference in the lengths of the respective curves on the planned surface model and the actual surface model.

11. The apparatus according to claim 1, wherein the computer program code is further configured to, with the at least one processor, cause the apparatus to:
detect an error associated with installation of the at least one mesh, in response to detecting, subsequent to installation of the at least one mesh on the rock surface, the at least one mesh not to overlap with at least one adjacent mesh; and
update the meshing plan by configuring at least one additional mesh to be installed between the at least one mesh and the at least one adjacent mesh.

12. The apparatus according to claim 2, wherein the computer program code is further configured to, with the at least one processor, cause the apparatus to:
apply a smoothing filter on the scanning data to obtain the actual surface model.

13. A mesh installation rig comprising the apparatus according to claim 1.

14. A computer-implemented method, comprising:
obtaining a meshing plan indicative of at least one of: a planned position of at least one mesh for installation of the at least one mesh to a rock surface, or a planned position of at least one fastener for fastening the at least one mesh to the rock surface;
obtaining a planned surface model of the rock surface;
obtaining an actual surface model of the rock surface;
detecting a discrepancy between the planned surface model and the actual surface model;
updating the meshing plan based on the detected discrepancy; and
controlling the mesh installation based on the updated meshing plan.

15. A non-transitory computer readable medium comprising computer program instructions which, when executed by an apparatus, cause the apparatus at least to:
obtain a meshing plan indicative of at least one of: a planned position of at least one mesh for installation of the at least one mesh to a rock surface, or a planned position of at least one fastener for fastening the at least one mesh to the rock surface;
obtain a planned surface model of the rock surface;
obtain an actual surface model of the rock surface;
detect a discrepancy between the planned surface model and the actual surface model;
update the meshing plan based on the detected discrepancy; and
control the mesh installation based on the updated meshing plan.
